(19) United States
(12) Patent Application Publication
(10) Pub. No.: US 2026/0109880 A1
(43) Pub. Date: Apr. 23, 2026

(54) DIAMOND-BASED POLISHING COMPOSITIONS WITH IMPROVED SILICON CARBIDE REMOVAL RATE

(71) Applicant: Diamond Innovations, Inc., Worthington, OH (US)

(72) Inventors: Tim Dumm, Westerville, OH (US); Charles Erik Moritz, Galena, OH (US); Thomas Draskovic, Columbus, OH (US)

(21) Appl. No.: 19/159,753

(22) PCT Filed: Mar. 28, 2024
(86) PCT No.: PCT/IB2024/053017

§ 371 Date: Aug. 26, 2025

Related U.S. Application Data
(60) Provisional application No. 63/455,629, filed on Mar. 30, 2023.
(60) Provisional application No. 63/601,282, filed on Nov. 21, 2023.

(51) Int. Cl. C09G 1/02; C09K 3/14; H10P 52/40

(52) U.S. Cl. CPC C09G 1/02; C09K 3/1409; H10P 52/402

(57) ABSTRACT

Provided is a polishing composition for polishing semiconductor wafer surfaces, including a surface-modified monocrystalline diamond with a D(50) particle size ranging from about 0.10 μm to about 1 μm; a vehicle selected from the group consisting of water-based vehicles, glycol-based vehicles, oil-based vehicles, and hydrocarbon-based vehicles; and optionally one or more additives. Further presented are associated methods for polishing semiconductor wafer surfaces.

### FIELD OF THE DISCLOSURE

The present disclosure relates to diamond-based slurry compositions for polishing semiconductor wafer surfaces, and to associated methods for polishing semiconductor wafer surfaces.

### BACKGROUND

Semiconductor wafers encompassing the ability to operate more efficiently to achieve a significant reduction in power-consumption are highly desirable. One studied industry area includes polishing of semiconductor wafer surfaces in the electronics industry by a process that is known as chemical-mechanical polishing (CMP), where a slurry is both mechanically and chemically active to remove interfering deposited materials and particles from semiconductor wafer surfaces.

To conclude the semiconductor manufacturing process, the core idea is that semiconductor wafer surfaces are polished to provide an attractive smooth surface, and to obtain precise dimensions for the semiconductor wafer surfaces.

The manufacturing process for making semiconductor wafers involves, as a final step, a CMP-process. This step provides a semiconductor wafer surface that is substantially free of surface defects attained from previous grinding cycles, and moreover, creates a semiconductor wafer surface that is ready for use by the end-user. However, an inherent issue, which cannot be ignored is that this process principally uses slurries that are first and foremost expensive, environmentally harmful, and unfavorably produce a low material removal rate. What is more, a further downside is that the CMP-process takes several hours to accomplish, and thus consumes significant amounts of expensive and environmentally harmful slurries.

The current general practice of manufacturing semiconductor wafers typically incorporates a CMP-step either after the fine-grinding step, or during the final lapping step. At the end of these two steps, the surface roughness of the semiconductor wafers is typically in a range of from about 1.5 nm to about 3 nm. The CMP-process is then employed to reduce the surface roughness to about 0.5 nm, or in some case, to even less. Simply put, the polishing-process using currently available CMP-slurries formulated specifically for semiconductor wafers may unfavorably take several hours to complete. Given the notion that CMP-slurries are expensive, and moreover, utilize concomitant harsh chemicals for affecting the removal rate and the surface-quality of the semiconductor wafers, these characteristics therefore naturally place strict restrictions on their use. The electronics industry is thus desirous of implementing optimized polishing solutions and processes. With that in mind, adaptable polishing processes and compositions are continuously sought out in the electronics sector to allow the end-user to either fully eliminate the CMP-step, or to significantly reduce the time, and the CMP-slurry consumption that is typically needed. This will ultimately result in lower process-costs and optimized lower cycle-times with improved throughput.

In view of the foregoing, there is therefore a need for polishing compositions and processes conferring a high material removal rate from the semiconductor wafer surface, along with reducing the surface roughness of the semiconductor wafer equivalent to CMP-quality that are not cumbersome and time-consuming, nor costly, and that are further devoid of harsh chemicals to optimize the polishing cycle of semiconductor wafer surfaces.

### SUMMARY

Provided is a polishing composition for polishing a surface of a semiconductor wafer, including a surface-modified monocrystalline diamond with a D(50) particle size ranging from about 0.10 μm to about 1 μm; a vehicle selected from the group consisting of water-based vehicles, glycol-based vehicles, oil-based vehicles, and hydrocarbon-based vehicles; and optionally one or more additives.

Optionally, the D(50) particle size of the surface-modified monocrystalline diamond ranges from about 0.25 μm to about 0.50 μm.

Optionally, the D(50) particle size of the surface-modified monocrystalline diamond ranges from about 0.25 μm to about 0.75 μm.

Optionally, the D(50) particle size of the surface-modified monocrystalline diamond ranges from about 0.50 μm to about 0.75 μm.

Optionally, the D(50) particle size of the surface-modified monocrystalline diamond ranges from about 0.75 μm to about 1 μm.

Optionally, the one or more additives is selected from the group consisting of dispersing agents, pH modifiers, pH buffering agents, surfactants, polymers, complexing agents, rheology modifiers, chelating agents, defoamers, wetting agents, oxidizing agents, and biocides.

Optionally, a material removal rate of silicon carbide (SiC) ranges from about 1.3 μm/hr to about 8.2 μm/hr.

Optionally, the material removal rate of the SiC ranges from about 1.3 μm/hr to about 7.2 μm/hr.

Optionally, the material removal rate of the SiC ranges from about 1.3 μm/hr to about 3.3 μm/hr.

Optionally, the material removal rate of the SiC ranges from about 3.3 μm/hr to about 7.2 μm/hr.

Optionally, the material removal rate of the SiC ranges from about 3.3 μm/hr to about 8.2 μm/hr.

Optionally, the material removal rate of the SiC ranges from about 7.2 μm/hr to about 8.2 μm/hr.

Optionally, a material removal rate of the SiC is increased by a range of from about 185% to about 245% compared to a polishing composition including monocrystalline diamond particles or polycrystalline diamond particles.

Optionally, a surface roughness of a SiC wafer is substantially similar, or lower compared to a surface roughness of a SiC wafer polished with a polishing composition including monocrystalline diamond particles or polycrystalline diamond particles when the D(50) particle size of the surface-modified monocrystalline diamond ranges from about 0.25 μm to about 1 μm.

Optionally, the surface-modified monocrystalline diamond is present in a weight of from about 0.5 weight percent (wt. %) to about 5 wt. % based on a total weight of the polishing composition.

Optionally, the surface-modified monocrystalline diamond is present in a weight of from about 0.5 wt. % to about 2.5 wt. % based on the total weight of the polishing composition.

Optionally, the vehicle is present in a volume of from about 10 vol. % to about 70 vol. % based on a total volume of the polishing composition.

Optionally, the SiC is monocrystalline silicon carbide.

Optionally, the surface-modified monocrystalline diamond includes one or more spikes, and one or more pits.

Optionally, the semiconductor wafer polishing composition excludes potassium permanganate.

Further provided is a method for polishing a surface of a semiconductor wafer, including contacting the surface of the semiconductor wafer with a polishing pad applied with the aforementioned polishing composition. The polishing pad applied with the polishing is next moved relative to the semiconductor wafer. Finally, at least a portion of the semiconductor wafer is abraded, so as to polish the semiconductor wafer.

Other systems, methods, features and advantages will be, or will become apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with the embodiments of the disclosure. It is to be understood that both the foregoing general description and the following detailed description of the present disclosure are examples and explanatory and are intended to provide further explanation of the disclosure as claimed.

### BRIEF DESCRIPTION OF THE DRAWINGS

The accompanying drawings, which are included to provide a further understanding of the subject matter and are incorporated in and constitute a part of this specification, illustrate implementations of the subject matter and together with the description serve to explain the principles of the disclosure.

FIG. 1A shows an exemplary microstructure of a surface-modified monocrystalline diamond crystal in accordance with an exemplary embodiment of the present subject matter.

FIG. 1B shows an exemplary microstructure of a monocrystalline diamond crystal in accordance with an exemplary embodiment of the present subject matter.

FIG. 2 shows a flow diagram demonstrating the individual process steps for polishing a surface of a semiconductor wafer in accordance with an exemplary embodiment of the present subject matter.

FIG. 3 shows (i) material removal rates of silicon carbide from a silicon carbide wafer (vertical bars) viewed on the left-hand side y-axis, and (ii) surface roughness (black closed dots) viewed on the right-hand side y-axis by using either, (I) a polishing composition employing a surface-modified monocrystalline diamond (Smmd) with a D(50) particle size ranging from about 0.25 μm to about 1 μm, (II) a polishing composition employing a monocrystalline diamond with a D(50) particle size ranging from about 0.25 μm to about 1 μm, or (III) a polishing composition employing a polycrystalline diamond with a D(50) particle size ranging from about 0.25 μm to about 1 μm in accordance with an exemplary embodiment of the present subject matter.

### DETAILED DESCRIPTION

Unless defined otherwise all technical and scientific terms used herein have the same meaning as commonly understood to one of ordinary skill in the art to which the presently described subject matter pertains.

Where a range of values is provided, for example, concentration ranges, percentage ranges, or ratio ranges, it is understood that each intervening value, to the tenth of the unit of the lower limit, unless the context clearly dictates otherwise, between the upper and lower limit of that range and any other stated or intervening value in that stated range, is encompassed within the described subject matter. The upper and lower limits of these smaller ranges may independently be included in the smaller ranges, and such embodiments are also encompassed within the described subject matter, subject to any specifically excluded limit in the stated range. Where the stated range includes one or both of the limits, ranges excluding either or both of those included limits are also included in the described subject matter.

The following definitions set forth the parameters of the described subject matter.

As used herein this disclosure, the term “diamond particle” refers to a discrete body, or discrete bodies made of diamond. As used herein this disclosure, the term “diamond particle” is also considered a diamond crystal, or a diamond grain.

As used herein this disclosure, the terms “wt. %” and “vol. %” refer to a weight percent and a volume percent, respectively, based on a total weight, or a total volume of a polishing composition for polishing a surface of a semiconductor wafer.

As used herein this disclosure, the term “diamond abrasive” refers to a diamond material used to wear away softer material than the diamond abrasive itself.

As used herein this disclosure, the term “material removal” refers to a weight of a workpiece removed in a given period of time reported in milligrams, grams, etc.

As used herein this disclosure, the term “material removal rate” refers to material removed divided by the time-interval reported as for example material removed from the surface of the semiconductor wafer in microns per hour, milligrams per minute, grams per hour.

As used herein this disclosure, the term “monocrystalline diamond” refers to a diamond having an overall flat structural surface that is formed either by a high-pressure high-temperature (HPHT) consolidation operation, or to a diamond that is naturally formed. Fracture of the monocrystalline diamond proceeds along atomic cleavage-planes. A monocrystalline diamond particle breaks relatively easily at the cleavage-planes.

As used herein this disclosure, the term “polycrystalline diamond” refers to a diamond formed by explosion-synthesis resulting in a polycrystalline particle-structure. Each polycrystalline diamond particle may include large numbers of microcrystallites less than about 100 angstroms in size. Polycrystalline diamond particles do not have cleavage planes.

As used herein this disclosure, the term “superabrasive ultrahard material”, or simply “superabrasive material” refers to an abrasive material demonstrating superior hardness and abrasion resistance, which may exhibit Knoop indentation hardness typically surpassing 2000, as found in the following, but not limited to crystal diamond, polycrystalline diamond (PCD), thermally stable polycrystalline diamond, chemical vapor deposition (CVD) diamond, metal matrix diamond composites, ceramic matrix diamond composites, nanodiamond, cubic boron nitride (cBN), polycrystalline cubic boron nitride (PcBN), or any combinations thereof. The term “abrasive”, as used herein, refers to any material used to wear away softer material.

As used herein this disclosure, the term “workpiece” refers to parts, or objects, from which, material is removed by polishing, lapping, or other material removal methods.

As used herein this disclosure, the term “surface-modified monocrystalline diamond” refers to diamonds made of unique, chemically man-made, or synthetic diamond crystals that typically provide an improved performance with respect to material removal rates from semiconductor wafer surfaces, when performing polishing, over for instance monocrystalline, or polycrystalline diamonds. The unique irregularly shaped surface characteristics of the surface-modified monocrystalline diamonds disclosed herein favorably deliver remarkable material removal rates from semiconductor wafer surfaces. They further encompass the added benefit of adding an excellent surface-finish imparted on the semiconductor wafer surface, due to the inherent distinctive multi-faceted diamond surface. This distinct irregular surface provides a plurality of small spikes and pits to reduce the surface roughness of the polished semiconductor wafer.

As used herein this disclosure, the term “multi-faceted” refers to multiple edges located around flat faces.

As used herein this disclosure, the term “surface roughness” refers to a measurement of a two-dimensional image that quantifies an extent, or a degree of pits and spikes of an object's surfaces, edges, and boundaries, as stated in the CLEMEX image analyzer, Clemex Vision User's Guide PE 3.5, 2001. Surface roughness is determined by a ratio of the convex perimeter, which is divided by the perimeter.

$$Surface roughness = Convex perimeter / Perimeter .$$

As the degree of pits and spikes increases, the surface roughness factor decreases.

As used herein this disclosure, the term “sphericity” refers to an estimate of an enclosed area of a two-dimensional image or object (4πA) divided by the square of perimeter (p²).

$$Sphericity = 4 π A / {p}^{2} .$$

The surface roughness of semiconductors is an important factor to consider for the electrical properties of semiconductor wafers. The mobility of electrons in semiconductor wafers is, in part, influenced by the thickness of the semiconductor wafer surface, and the size and shape-configurations of its surface edges. By polishing the semiconductor wafer surface, this advantageously transforms an otherwise dull rough surface to one that is substantially flat and smooth with mirror-like property, and one that is substantially free of negatively influencing particles to the overall electronic operation of the semiconductor wafer.

As used herein this disclosure, the term “perimeter” refers to the boundary of a closed plane figure, or the sum of all borders of a two-dimensional image.

As used herein this disclosure, the term “convex perimeter” refers to a line joining Feret tangent points, where Feret is a distance between two parallel tangents touching a boundary on each side of a two-dimensional image or object.

As used herein this disclosure, the term “pit” refers to an indentation, or crevice in a particle, either an indentation, or crevice in a two-dimensional image, or an indentation or crevice in an object.

As used herein this disclosure, the term “spike” refers to a sharp projection or protrusion pointing outward from a centroid of a particle, a sharp projection or protrusion pointing outward from a centroid of a two-dimensional image, or a sharp projection or protrusion pointing outward from an object.

As used herein, the term “surface area” refers to the external surface of a particle. When used with a plurality of particles, i.e., powder, the term specific surface area is used and is reported as surface area per gram of powder.

As used herein this disclosure, the term “about” is meant to mean plus or minus 5% of the numerical value of the number, with which, it is being used in the claims and herein this disclosure. Thus, “about” may be used to provide flexibility to a numerical range endpoint, in which, a given value may be “above” or “below” the given value. As such, for example a value of 50% may be intended to encompass a range, which may be defined by for example ranges like 47.5%-52.25%, 47.5%-52.5%, 47.75%-50%, 50%-52.5%, 48%-48.5%, 48%-48.75%, 48%-49%, 48%-49.5%, 48%-49.75%, 48%-50%, 48%-50.25%, 48%-50.5%, 48%-50.75%, 48%-51%, 48%-51.5%, 48%-51.75%, 48%-52%, 48%-52.25%, 48%-52.5%, 48.25%-48.5%, 48.25%-48.75%, 48.25%-49%, 48.25%-49.5%, 48.25%-49.75%, 48.25%-50%, 48.25%-50.25%, 48.25%-50.5%, 48.25%-50.75%, 48.25%-51%, 48.25%-51.35%, 48.25%-51.5%, 48.25%-51.75%, 48.25%-52%, 48.25%-52.25%, 48.25%-52.5%, 48.5%-48.75%, 48.5%-49%, 48.5%-49.5%, 48.5%-49.75%, 48.5%-50%, 48.5%-50.25%, 48.5%-50.5%, 48.5%-50.75%, 48.5%-51%, 48.5%-51.35%, 48.5%-51.5%, 48.5%-51.75%, 48.5%-52%, 48.5%-52.25%, 48.5%-52.5%, 49%-49.25%, 49%-49.5%, 49%-49.75%, 49%-50%, 49%-50.25%, 49%-50.5%, 49%-50.75%, 49%-51%, 49%-51.35%, 49%-51.5%, 49%-51.75%, 49%-52%, 49%-52.25%, 49%-52.5% 49.5%-49.75%, 49.5%-50%, 49.5%-50.25%, 49.5%-50.5%, 49.5%-50.75%, 49.5%-51%, 49.5%-51.5%, 49.5%-51.75%, 49.5%-52%, 49.5%-52.25%, 49.5%-52.5%, 49.75%-50%, 49.75%-50.25%, 49.75%-50.5%, 49.75%-50.75%, 49.75%-51%, 49.75%-51.35%, 49.75%-51.5%, 49.75%-51.75%, 49.75%-52%, 49.75%-52.25%, 49.75%-52.5%, 50%-50.25%, 50%-50.5%, 50%-50.75%, 50%-51%, 50%-51.35%, 50%-51.5%, 50%-52%, 50%-52.25%, 50%-52.5%.

As used herein this disclosure, the term “D(50)” refers to a particle size corresponding to 50% of a volume of the sampled particles being smaller than, and 50% of a volume of the sampled particles being greater than the recited D(50) value.

As used herein this disclosure, the term “D(99)” refers to a particle size corresponding to 99% of a volume of the sampled particles being smaller than, and 1% of a volume of the sampled particles being greater than the recited D(99) value.

Wherever used throughout the disclosure, the term “generally” has the meaning of “typically” or “closely” or “within the vicinity or range of”.

As used herein this disclosure, the term “substantially” refers to the complete or nearly complete extent or degree of an action, characteristic, property, state, structure, item, or result. It is meant to cover plus or minus 6.25% of the numerical value of the number, with which, it is being used in the claims, and otherwise herein this disclosure.

As used herein this disclosure, the term “surfactant” refers to compounds that lower the surface tension between for example two liquids, between a gas and a liquid, or between a liquid and a solid. A person having ordinary skill in the art would know that surfactants may commonly include for example the following class of chemical constituents, but without limitation, detergents, wetting agents, emulsifiers, foaming agents, and dispersants.

As used herein this this disclosure, the term “surface tension” refers to the tendency of liquid surfaces to shrink into the minimum surface-area as possible at rest.

As used herein this disclosure, the term “amphoteric” refers to compounds that are able to react both as a base and as an acid.

As used herein this disclosure, the term “rheology modifier” refers to compounds, which are added to the polishing compositions forming the diamond slurries to increase their viscosity, and to control the flowing properties of the diamond slurries.

As used herein this disclosure, “physical vapor deposition (PVD)” refers to a variety of vacuum deposition methods, which can be used to produce thin films and coatings. PVD is characterized by a process, in which, the material that is deposited goes from a condensed phase to a vapor phase, and then back to a thin film condensed phase. The most common PVD processes are sputtering and evaporation.

As used herein this disclosure, “chemical vapor deposition (CVD)” refers to a method, where the substrate is exposed to one or more volatile precursors, which react and/or decompose on the substrate-surface to produce the desired deposit. Frequently, volatile by-products are also produced, which are removed by gas flow through a reaction chamber.

### Diamond-Based Polishing Compositions for Polishing a Surface of Semiconductor Wafers

The current disclosure is based on the premise of presenting a polishing composition including a surface-modified monocrystalline diamond for polishing a surface of virtually any semiconductor wafer. The key features of the polishing composition of the subject matter are the favorably high material removal rates from the semiconductor wafer surface, along with the added benefit of reducing the surface roughness of the semiconductor wafer equivalent to chemical-mechanical polishing (CMP)-quality in less time. Additionally, making the semiconductor polishing composition is not expensive, and the polishing composition is further advantageously devoid of any harsh chemicals to optimize the overall post-formation polishing cycle of semiconductor wafers.

The polishing composition may typically include a surface-modified monocrystalline diamond with a D(50) particle size ranging from about 0.10 μm to about 1 μm. In some examples, the polishing composition includes the surface-modified monocrystalline diamond having a D(50) particle size ranging from about 0.25 μm to about 1 μm. In other examples, the polishing composition includes the surface-modified monocrystalline diamond having a D(50) particle size ranging from about 0.35 μm to about 1 μm. In still other examples, the polishing composition includes the surface-modified monocrystalline diamond having a D(50) particle size ranging from about 0.45 μm to about 1 μm. In yet other examples, the polishing composition includes the surface-modified monocrystalline diamond having a D(50) particle size ranging from about 0.55 μm to about 1 μm. In even other examples, the polishing composition includes the surface-modified monocrystalline diamond having a D(50) particle size ranging from about 0.65 μm to about 1 μm. In further other examples, the polishing composition includes the surface-modified monocrystalline diamond having a D(50) particle size ranging from about 0.75 μm to about 1 μm. In even further other examples, the polishing composition includes the surface-modified monocrystalline diamond having a D(50) particle size ranging from about 0.85 μm to about 1 μm. In even further additional other examples, the polishing composition includes the surface-modified monocrystalline diamond having a D(50) particle size ranging from about 0.95 μm to about 1 μm.

The polishing composition may also include the surface-modified monocrystalline diamond with a D(50) particle size ranging from about 0.10 μm to about 0.25 μm, ranging from about 0.25 μm to about 0.35 μm, ranging from about 0.10 μm to about 0.35 μm, ranging from about 0.35 μm to about 0.45 μm, ranging from about 0.45 μm to about 0.55 μm, ranging from about 0.25 μm to about 0.45 μm, ranging from about 0.25 μm to about 0.55 μm, ranging from about 0.35 μm to about 0.55 μm, ranging from about 0.55 μm to about 0.65 μm, ranging from about 0.65 μm to about 0.75 μm, ranging from about 0.75 μm to about 0.85 μm, ranging from about 0.25 μm to about 0.85 μm, ranging from about 0.30 μm to about 0.85 μm, ranging from about 0.35 μm to about 0.85 μm, ranging from about 0.40 μm to about 0.85 μm, ranging from about 0.45 μm to about 0.85 μm, ranging from about 0.50 μm to about 0.85 μm, ranging from about 0.55 μm to about 0.85 μm, ranging from about 0.60 μm to about 0.85 μm, ranging from about 0.65 μm to about 0.85 μm, ranging from about 0.70 μm to about 0.85 μm, ranging from about 0.80 μm to about 0.85 μm, ranging from about 0.25 μm to about 0.90 μm, ranging from about 0.30 μm to about 0.90 μm, ranging from about 0.35 μm to about 0.90 μm, ranging from about 0.40 μm to about 0.90 μm, ranging from about 0.45 μm to about 0.90 μm, ranging from about 0.50 μm to about 0.90 μm, ranging from about 0.55 μm to about 0.90 μm, ranging from about 0.60 μm to about 0.90 μm, ranging from about 0.65 μm to about 0.90 μm, ranging from about 0.70 μm to about 0.90 μm, ranging from about 0.75 μm to about 0.90 μm, ranging from about 0.80 μm to about 0.90 μm, ranging from about 0.85 μm to about 0.90 μm, ranging from about 0.25 μm to about 0.95 μm, ranging from about 0.30 μm to about 0.95 μm, ranging from about 0.35 μm to about 0.95 μm, ranging from about 0.40 μm to about 0.95 μm, ranging from about 0.45 μm to about 0.95 μm, ranging from about 0.50 μm to about 0.95 μm, ranging from about 0.55 μm to about 0.95 μm, ranging from about 0.60 μm to about 0.95 μm, ranging from about 0.65 μm to about 0.95 μm, ranging from about 0.70 μm to about 0.95 μm, ranging from about 0.75 μm to about 0.95 μm, ranging from about 0.80 μm to about 0.95 μm, ranging from about 0.85 μm to about 0.95 μm, or ranging from about 0.90 μm to about 0.95 μm.

For determining a specific diamond particle size, one having ordinary skill in the art may typically employ either dynamic digital image analysis (DIA), static laser light scattering (SLS) also known as laser diffraction, or visual measurement by electron microscopy, a technique known as image analysis and light obscuration. Each method covers a characteristic size range within which measurement is possible. These ranges partly overlap. However, the results for measuring the same sample may vary all depending on the particular method that is used. A skilled artisan who wants to determine particle size distributions would readily know how each mentioned method is commonly performed and practiced. Thus, the reader is directed to for example, (i) “Comparison of Methods. Dynamic Digital Image Analysis, Laser Diffraction, Sieve Analysis”, Retsch Technology, and (ii) the scientific publication by Kelly et al., “Graphical comparison of image analysis and laser diffraction particle size analysis data obtained from the measurements of particle systems”, AAPS PharmSciTech. 2006 Aug. 18; Vol. 7(3):69, to further gain insight into each procedure and methodology, all of which documents, are incorporated herein by reference in their entirety.

The polishing composition may generally include the surface-modified monocrystalline diamond being present in a weight of from about 0.5 weight percent (wt. %) to about 5 wt. % based on a total weight of the polishing composition. In some examples, the surface-modified monocrystalline diamond is present in a weight of from about 1 wt. % to about 5 wt. % based on a total weight of the polishing composition. In other examples, the surface-modified monocrystalline diamond is present in a weight of from about 1.5 wt. % to about 5 wt. % based on a total weight of the polishing composition. In yet other examples, the surface-modified monocrystalline diamond is present in a weight of from about 2 wt. % to about 5 wt. % based on a total weight of the polishing composition. In still other examples, the surface-modified monocrystalline diamond is present in a weight of from about 2.5 wt. % to about 5 wt. % based on a total weight of the polishing composition. In further other examples, the surface-modified monocrystalline diamond is present in a weight of from about 3 wt. % to about 5 wt. % based on a total weight of the polishing composition. In even other examples, the surface-modified monocrystalline diamond is present in a weight of from about 3.5 wt. % to about 5 wt. % based on a total weight of the polishing composition. In even further other examples, the surface-modified monocrystalline diamond is present in a weight of from about 4 wt. % to about 5 wt. % based on a total weight of the polishing composition. In even other embodiments, the surface-modified monocrystalline diamond is present in a weight of from about 4.5 wt. % to about 5 wt. % based on a total weight of the polishing composition.

The polishing composition may also include the surface-modified monocrystalline diamond being present in a weight of from about 0.5 wt. % to about 1 wt. %, from about 1 wt. % to about 1.5 wt. %, from about 1.5 wt. % to about 2 wt. %, from about 0.5 wt. % to about 1.5 wt. %, from about 0.5 wt. % to about 2 wt. %, from about 1 wt. % to about 2 wt. %, from about 1 wt. % to about 2.5 wt. %, from about 1.5 wt. % to about 2.5 wt. %, from about 1 wt. % to about 3 wt. %, from about 1.5 wt. % to about 3 wt. %, from about 2 wt. % to about 2.5 wt. %, from about 2.5 wt. % to about 3 wt. %, from about 3 wt. % to about 3.5 wt. %, from about 2 wt. % to about 3 wt. %, from about 2 wt. % to about 3.5 wt. %, from about 2 wt. % to about 4 wt. %, from about 2.5 wt. % to about 4 wt. %, from about 3 wt. % to about 4 wt. %, from about 3.5 wt. % to about 4 wt. %, or from about 3.5 wt. % to about 4.5 wt. % based on a total weight of the polishing composition.

The surface-modified monocrystalline diamond disclosed herein includes unique, man-made, or synthetic diamond crystals that typically provides improved performance over for instance conventional monocrystalline or polycrystalline diamonds. The unique irregularly shaped surface characteristics of the surface-modified monocrystalline diamond disclosed herein favorably deliver remarkable material removal rates from the semiconductor wafer, with the additionally added benefit of providing an excellent surface finish conferred on the semiconductor wafer surface due to the inherent distinctive multi-faceted diamond surface. This distinct irregular surface provides small cutting points to reduce the overall surface roughness of the semiconductor wafer.

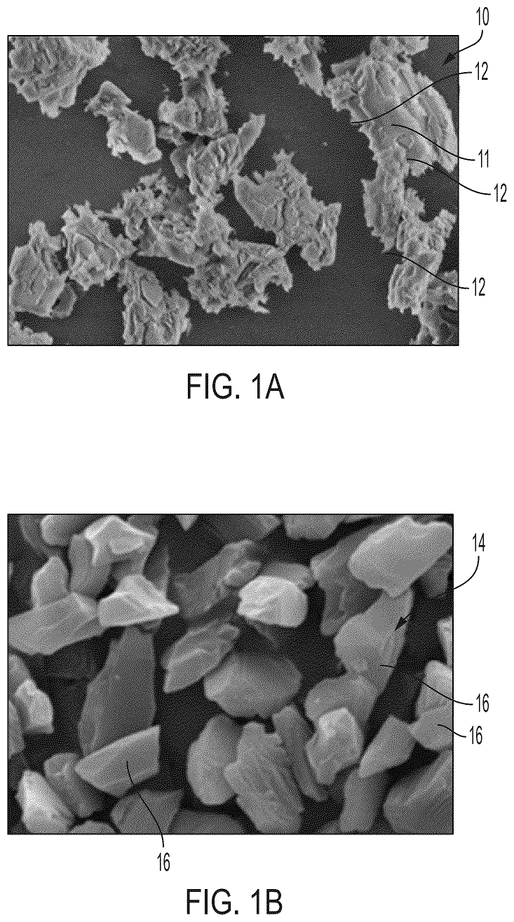

Now, directing the attention of the reader to the Figures, this is best observed in FIG. 1A, which depicts an exemplary microstructure of a chemically surface-modified monocrystalline diamond 10 disclosed herein. The unique small spikes, which have specifically been tailored to facilitate an optimized material removal are demonstrated with numeral 12 in FIG. 1A. This is in stark contrast to for example a conventional monocrystalline diamond crystal 14 having substantially an overall flat structural surface 16, as demonstrated in FIG. 1B. Hence, at least due to the multi-faceted surface-signature, which is entirely lacking on the surface 16 of the monocrystalline diamond crystal 14, the material removal rates will also concurrently be restricted, and critically impeded using the monocrystalline diamond crystal 14, in comparison to the surface-modified monocrystalline diamond crystal 10 disclosed herein and shown in FIG. 1A. As further shown in FIG. 1A, the surface-modified monocrystalline diamond particles 10 essentially exhibit spikes 12 and pits 11, which are clearly deficient in conventional monocrystalline diamond 14 shown in FIG. 1B. The essential functionality of the spikes 12, is particularly that they act as cutting edges when used in free-abrasive slurry applications. It has been discovered that the performance of the surface-modified monocrystalline diamond particles 10 significantly improves when used in free abrasive lapping applications within a liquid slurry or suspension. When the surface-modified monocrystalline diamond particles 10 are used in a fixed bond system, the pits 11 and the spikes 12 help secure the particle within the bond system. The lengths of the spikes 12 and depths of the pits 11 vary according to the modification-treatment parameters. The average depth of the pits 11 on a diamond particle 10, typically ranges in size from about 5% to about 70% of the longest length of the surface-modified monocrystalline diamond particle 10. The surface-modified monocrystalline diamond particles 10 further exhibit unique characteristics in surface roughness, sphericity and material removal. The surface-modified monocrystalline diamond particles 10 demonstrate a surface roughness of less than about 0.95. Surface roughness of from about 0.50 to about 0.80, and from about 0.50 to about 0.70 are also demonstrated. Surface roughness of the surface-modified monocrystalline diamond particles 10 is a function of the size of metal particle(s), amount of the metal particle(s) in contact with the diamond 10, reaction-time, and temperature, which is used in the process. As the surface roughness increases, the ability of the diamond particle 10 to perform material removal in a lapping process also increases. This is likely attributed to the increased number of cutting points that the surface-modification process confers on the diamond particles 10. Moreover, the surface-modified monocrystalline diamond particles 10 demonstrate sphericity of less than about 0.70. Sphericity readings of about 0.2 to about 0.5, and about 0.25 to 0.40 are also demonstrated. Although sphericity is an independent feature from the surface roughness, there is a positive correlation between the sphericity and the lapping performance of the surface-modified monocrystalline diamond particles 10. Moreover, there is a positive correlation between the weight loss of a diamond particle 10 and the lapping performance. Thus, as the weight loss of the diamond particle 10 increases, the diamond particle 10 becomes more aggressive in its ability to remove material form the surface of a semiconductor wafer. The foregoing technical parameters are explained in greater detail in at least U.S. Pat. Nos. 8,182,562B2; 8,652,226B2; and 8,927,101B2, which documents, are hereby incorporated herein in their entirety.

Now, the processes of forming the surface-modified monocrystalline diamond 10 will be explained.

In one example, a reactive coating is used to modify the surface of the diamond. Such reactive coatings may generally include but are not limited to alkali metal hydroxides, such as lithium hydroxide, sodium hydroxide, potassium hydroxide, potassium carbonate, sodium peroxide, potassium dichromate and potassium nitrate. The reactive coatings may also include a combination of alkali metal hydroxides.

Still other examples of metals that may be utilized as the reactive coating may be chosen from those included in at least Group VIII of the Periodic table, their metal compounds and combinations thereof. Other examples of material that may be used as reactive coatings include the catalyst metals taught in U.S. Pat. No. 2,947,609 and the catalyst metals taught in U.S. Pat. No. 2,947,610, which documents are incorporated herein by reference in their entirety.

In one particular example, a nickel (Ni) metal-coating is used as the reactive coating. The used metal-coating may typically be about 10 wt. % to about 90 wt. % Ni, or about 10 wt. % to about 60 wt. % with a balance of diamond particles. However, it should be noted that these ratios are a matter of economic efficiency rather than technical effectiveness. In one example, the metal-coating at least partially covers the diamond particles. Alternatively, the metal-coating may uniformly surround each diamond particle. It is not necessary that the metal is chemically bonded to the diamond. Nickel and/or nickel alloys may be used as a coating for the diamond. A method of application of the nickel to the diamond is with an electroless-deposition process. However, methods such as electrolytic plating, physical vapor deposition (PVP) or chemical vapor deposition (CVD) may equally be used to coat the diamond particles with a layer of nickel.

In one example, diamond particles are coated with from about 10 wt. % to about 60 wt. % nickel phosphorous coating. The coating process initially subjects the uncoated diamond particles to a solution of colloidal palladium. The fine palladium particles uniformly adsorb onto the surface of the diamond making the surface autocatalytic for electroless deposition of nickel. In the next stage of the process, the activated diamond is placed into nickel sulfamate solution containing about 10 grams per liter dissolved nickel. While the activated diamond and the nickel suspension is mixing, sodium hypophosphate is added to the suspension and the temperature of the coating bath is maintained at about 80° C. When the sodium hypophosphate solution is added, all of the dissolved nickel in solution will autocatalytically deposit onto the activated diamond surfaces.

Depending on how much nickel deposits onto the diamond, more nickel may be added by replacing the spent nickel/hypophosphate solution with fresh solutions and repeating the process. If uniformly coating the particle, several cycles may be required to obtain a sufficiently uniform coverage of nickel over each of the diamond particles. By monitoring the number of cycles and controlling the coating bath parameters like temperature, pH and mixing energy, the nickel content on the diamond is reproducible. It is not uncommon for the coated diamond to have some level of agglomerations as a consequence of the interactions of the diamond particles and nickel plating during the coating. So long as the individual diamond particles that include the agglomerates contain some amount of nickel coating, the presence of diamond agglomerates does not affect the quality of the process, and no attempt at removing agglomerates is required.

After the diamond particles have been coated with the nickel, the coated diamond particles are placed into a furnace, and in a hydrogen atmosphere, vacuum atmosphere, or an inert gas atmosphere, heated from about 650° C. to about 1000° C. Temperatures of about 700° C. to about 950° C., or about 800° C. to about 900° C. may routinely be used. The coated diamond coated with the nickel may be heated for a period of time of anywhere from about five minutes up to about five hours. Time periods ranging from about thirty minutes up to about two hours, or of about one to about two hours may typically be used.

After the heating cycle is complete, and the diamond particles are cooled, the modified diamond particles 10 are recovered by dissolving the nickel-coated surface-modified monocrystalline diamond particles 10 in acids. Acids that may typically be used can include hydrochloric acid, hydrofluoric acids, nitric acid, or combinations thereof. Acids, or combinations thereof, are added in an acid-to-coated-diamond ratio of 100:1 up to 1000:1 by volume. The mixture is then heated from about 100° C. to about 120° C. for a period of from about six to about eight hours. The solution is then cooled, and the liberated surface-modified monocrystalline diamond particles 10 settle, and the solution is decanted. The acid cleaning and heating steps may be repeated, until substantially all of the metal-coating has been digested.

Subsequently, any converted graphite (i.e. carbon from diamond that has been converted to graphite during the reaction with the nickel) is then removed from the surface-modified monocrystalline diamond particles 10 via any dissolution treatment-method known to a skilled person in the art. An example of a common dissolution procedure includes the oxidation of graphitic carbons by gradual heating range from about 150° C. to about 180° C. in an acidic solution containing a mixture of HNO₃ and H₂SO₄.

Depending on the furnace conditions chosen, more or less reaction may occur between the metal and the surface-modified monocrystalline diamond particles 10. The more the nickel etches into the surface-modified monocrystalline diamond 10, the more graphite is unfavorably formed, and thus, more weight is lost by the diamond. To completely dissolve the graphite, higher quantities of acid may be used, or additional dissolution treatments may be necessary. The surface-modified monocrystalline diamond particles 10 are then washed to remove acids and residue, such as in water. Subsequently, the surface-modified monocrystalline diamond particles 10 are dried in an oven, air dried, subjected to microwave drying, or other drying methods commonly known to a skilled person in the art.

Although nickel has been described, which is used in carrying out the process of modifying the surface of the diamond particles, other metals such as iron, or alternatively manganese, chrome or their metal compounds, or any combinations thereof may also be used for this purpose.

In another certain example of making surface-modified diamond particles 10, from about 10 wt. % to about 80 wt. % diamond particles, and from about 20 wt. % to about 90 wt. % iron particles are mixed using any appropriate mixing method that achieves a uniform mixture. In an example, the weighed portions of the iron and diamond particles are put into a jar, sealed and inserted into a mixing device such as a Turbula shaker-mixer (Glen Mills, Inc., Clifton, N.J., U.S.A.) for at least about one hour, or alternatively, about 30 minutes to about one hour. A binder may optionally be added to the mixture prior to mixing. Binders provide lubricity to particle surfaces allowing a denser packing and more intimate contact between the metal powder and diamond. Binders also help in holding a pressed body together as a green body.

The mixture is then compressed to create an intimate mixture of diamond particles and iron particles. Any method commonly known to one having ordinary skill in the art may be used to compress the diamond particles and iron particles, so long that they form an intimate mixture, and the particles are in close contact with one another. One method used to compress the mixture is to place the mixture into a fixed die-set on a press. An example of a suitable press is a Carver pellet press manufactured by Carver, Inc. (Wabash, Ind.). In the die-press, the mixture is subjected to a pressure from about 5 psi to about 50,000 psi, from about 10,000 psi to about 40,000 psi, or from about 15,000 psi to about 30,000 psi to form a pellet. Although pelletizing the mixture is taught, it is not necessary that the mixture of diamond and iron particles are strictly formed into a pellet, only that the particles are compressed to form intimate contact with one another. Isostatic or monostatic pressing with deformable tooling may also be used to achieve the intimate contact.

Alternatively, the diamond and iron mixture may also be compressed by pressing the mixture into a thin sheet that is several millimeters to several inches thick, i.e., by high pressure compaction rolls or briquetting rolls. The formed sheets may then be cut into smaller sections for further processing as discussed below. Another method of compressing the mixture of the iron and diamond particles includes mixing and extruding the mixture under pressure. Pelletizing the mixture of the diamond and iron particles via a pelletizer or tumbling the mixture in a tumbling apparatus are also alternative methods that may be used to compress the diamond and iron mixture. The pellets, bricks, or cakes formed by these methods may then be further processed as discussed below.

Additional methods of compressing the mixture of the iron and the diamond particles may include injection-molding, extrusion, pressing the mixture into a container or tape-casting. Alternatively, individual diamond particles may be coated with metal particles by ion implantation, sputtering, spray-drying, electrolytic coating, electroless coating, or any other applicable method so long as, the iron and diamond particles are in intimate contact with each other.

After compressing the mixture of diamond and iron particles, the compressed mixture, which may be in a pellet, an aggregate or other condensed form, is placed into a furnace, and in a hydrogen atmosphere, vacuum atmosphere, or an inert gas atmosphere, heated from about 650° C. to about 1000° C. Temperatures of typically about 700° C. to about 900° C., or about 750° C. to about 850° C. may be used. The compressed mixture may be heated for a period of time from about five minutes up to about five hours. Time-periods spanning from about thirty minutes up to about two hours, or of about one to about two hours may generally be used.

After the heating cycle is complete and the compressed mixture is cooled, the surface-modified diamond particles 10 are recovered by dissolving the iron particles in acids. Acids that may generally be used include hydrochloric acid, hydrofluoric acids, nitric acid, or combinations thereof. Acids, or combinations thereof, are added in an acid:compressed mixture (i.e., a pellet) ratio of 100:1 up to 1000:1 by volume. The mixture is then heated from about 100° C. to about 150° C. for a period of from about six to about eight hours. The solution is then cooled, and the liberated surface-modified monocrystalline diamond particles 10 settle, and the solution is decanted. The acid cleaning and heating steps may be repeated, until substantially all of the iron has been digested.

Subsequently, any converted graphite (i.e. carbon from diamond that has been converted to graphite during the reaction with the iron) is then removed from the surface-modified monocrystalline diamond particles 10 by way of any dissolution treatment method known in the art. An example of a common dissolution procedure includes the oxidation of graphitic carbons by gradual heating range between about 150° C. to about 180° C. in an acidic solution containing a mixture of HNO₃ and H₂SO₄.

Depending on the furnace conditions selected, more or less reaction may occur between the metal and the surface-modified monocrystalline diamond particles 10. The more the iron etches into the surface-modified monocrystalline diamond particles 10, the more graphite is disadvantageously formed, and thus, more weight is lost by the diamond. To completely dissolve the graphite, higher quantities of acid may be used, or additional dissolution treatments may be necessary. The surface-modified monocrystalline diamond particles 10 are then washed to remove acids and residue, such as in water. Subsequently, the surface-modified monocrystalline diamond particles 10 are dried in a furnace, air dried, subjected to microwave drying, or other drying methods routinely known to a person having ordinary skill in the art.

The polishing composition may include a vehicle typically selected from the group consisting of water-based vehicles, glycol-based vehicles e.g., ethylene glycol, propylene glycol, or mixtures thereof, oil-based vehicles, or hydrocarbon-based vehicles, and any desired combinations thereof. The polishing composition may include the foregoing vehicle elements in any possible combination, or volume % that is not inconsistent and incompatible with any of the objectives of the present subject matter, such as from about 10 vol. % to about 70 vol. %, from about 15 vol. % to about 70 vol. %, from about 20 vol. % to about 70 vol. %, from about 25 vol. % to about 70 wt. %, from about 30 vol. % to about 70 vol. %, from about 35 vol. % to about 70 vol. %, from about 40 vol. % to about 70 vol. %, from about 45 vol. % to about 70 vol. %, from about 50 vol. % to about 70 vol. %, from about 55 vol. % to about 70 vol. %, from about 60 vol. % to about 70 wt. %, from about 65 vol. % to about 70 vol. %, from about 10 vol. % to about 15, vol. %, from about 10 vol. % to about 20 vol. %, from about 10 vol. % to about 25 vol. %, from about 10 vol. % to about 30 vol. %, from about 10 vol. % to about 35 vol. %, from about 10 vol. % to about 40 vol. %, from about 10 vol. % to about 45 vol. %, from about 10 vol. % to about 50 vol. %, from about 10 vol. % to about 55 vol. %, from about 10 vol. % to about 60 vol. %, from about 10 vol. % to about 65 vol. %, from about 20 vol. % to about 25 vol. %, from about 20 vol. % to about 30 vol. %, from about 20 vol. % to about 35 vol. %, from about 20 vol. % to about 40 vol. %, from about 20 vol. % to about 45 vol. %, from about 20 vol. % to about 50 vol. %, from about 20 vol. % to about 55 vol. %, from about 20 vol. % to about 60 vol. %, or from about 20 vol. % to about 65 vol. %, from about 30 vol. % to about 35 vol. %, from about 30 vol. % to about 40 vol. %, from about 30 vol. % to about 45 vol. %, from about 30 vol. % to about 50 vol. %, from about 30 vol. % to about 55 vol. %, from about 30 vol. % to about 60 vol. %, from about 30 vol. % to about 65 vol. %, from about 40 vol. % to about 45 vol. %, from about 40 vol. % to about 50 vol. %, from about 40 vol. % to about 55 vol. %, from about 40 vol. % to about 60 vol. %, from about 40 vol. % to about 65 vol. %, from about 50 vol. % to about 55 vol. %, from about 50 vol. % to about 60 vol. %, from about 50 vol. % to about 65 vol. %, or from about 60 vol. % to about 65 vol. % based on a total volume of the polishing composition.

The polishing composition may further optionally include at least one or more additives, which may typically be selected from the group consisting of dispersing agents, pH modifiers, pH buffering agents, surfactants, polymers, complexing agents, rheology modifiers, chelating agents, defoamers, wetting agents, oxidizing agents, and biocides. The polishing composition may include the foregoing elements in any possible combination, or in any amount that is not inconsistent and incompatible with the objectives of the present disclosure.

In some examples, the foregoing optional constituents may be water-soluble, alcohol-soluble, or solvent-soluble. In other examples, the foregoing optional elements may be water-dispersible, alcohol-dispersible, or solvent-dispersible, which may typically include the following alcohols and solvents, but without limitation ethanol, methanol, isopropanol, butanol, cyclohexanol, acetone, hexane, heptane, toluene, or any combinations thereof. Such combinations may involve mixing for example water with an alcohol, water with a solvent, an alcohol with yet another alcohol, or an alcohol with a solvent.

In some examples, the polishing compositions disclosed herein may be formed as a slurry. In other examples, the polishing compositions disclosed herein may be formed as a suspension. In still other examples, the polishing compositions disclosed herein may be formed as a dispersion. In yet other examples, the polishing compositions disclosed herein may be formed as a paste. It is however to be emphasized that the polishing composition prepared with the surface-modified monocrystalline diamond can be formulated in any type, or form, that would be within the skills of one having ordinary skill in the art, which results in silicon carbide (SiC) removal rates from a SiC wafer surface ranging from about 1.3 μm/hr to about 8.2 μm/hr, ranging from about 2.2 μm/hr to about 8.2 μm/hr, ranging from about 3.2 μm/hr to about 8.2 μm/hr, ranging from about 4.2 μm/hr to about 8.2 μm/hr, ranging from about 5.2 μm/hr to about 8.2 μm/hr, ranging from about 6.2 μm/hr to about 8.2 μm/hr, ranging from about 7.2 μm/hr to about 8.2 μm/hr, ranging from about 1.3 μm/hr to about 2.2 μm/hr, ranging from about 2.2 μm/hr to about 3.2 μm/hr, ranging from about 3.2 μm/hr to about 4.2 μm/hr, ranging from about 1.3 μm/hr to about 4.2 μm/hr, ranging from about 2.2 μm/hr to about 4.2 μm/hr, ranging from about 3.2 μm/hr to about 4.2 μm/hr, ranging from about 4.2 μm/hr to about 5.2 μm/hr, ranging from about 4.2 μm/hr to about 6.2 μm/hr, ranging from about 4.2 μm/hr to about 7.2 μm/hr, ranging from about 5.2 μm/hr to about 6.2 μm/hr, ranging from about 6.2 μm/hr to about 7.2 μm/hr, ranging from about 1.3 μm/hr to about 3.3 μm/hr, ranging from about 1.3 μm/hr to about 7.2 μm/hr, ranging from about 3.3 μm/hr to about 7.2 μm/hr, or ranging from about 3.3 μm/hr to about 8.2 μm/hr.

The polishing composition can include surfactants including e.g. dispersing agents and wetting agents, such as, for example the following constituents but without limitation, cationic surfactants, anionic surfactants, non-ionic surfactants, amphoteric surfactants, or any mixtures and combinations thereof. The amount of the surfactant in the polishing composition may typically range from about 0.001 wt. % to about 0.05 wt. %, from about 0.001 wt. % to about 0.1 wt. %, from about 0.001 wt. % to about 0.5 wt. %, from about 0.001 wt. % to about 1 wt. %, from about 0.001 wt. % to about 1.5 wt. %, from about 0.001 wt. % to about 2 wt. %, from about 0.001 wt. % to about 2.5 wt. %, from about 0.001 wt. % to about 3 wt. %, from about 0.0001 wt. % to about 1 wt. %, from about 0.001 wt. % to about 0.1 wt. %, from about 0.001 wt. % to about 0.2 wt. %, from about 0.001 wt. % to about 0.3 wt. %, from about 0.001 wt. % to about 0.4 wt. %, from about 0.001 wt. % to about 0.6 wt. %, from about 0.001 wt. % to about 0.7 wt. %, from about 0.001 wt. % to about 0.8 wt. %, from about 0.001 wt. % to about 0.9 wt. %, from about 0.005 wt. % to about 0.1 wt. %, from about 0.005 wt. % to about 0.2 wt. %, from about 0.005 wt. % to about 0.3 wt. %, from about 0.005 wt. % to about 0.4 wt. %, from about 0.005 wt. % to about 0.5 wt. %, from about 0.005 wt. % to about 0.6 wt. %, from about 0.005 wt. % to about 0.7 wt. %, from about 0.005 wt. % to about 0.8 wt. %, from about 0.005 wt. % to about 0.9 wt. %, from about 0.005 wt. % to about 1 wt. %, from about 0.005 wt. % to about 0.05 wt. %, from about 0.005 wt. % to about 0.06 wt. %, from about 0.005 wt. % to about 0.07 wt. %, from about 0.005 wt. % to about 0.08 wt. %, or from about 0.005 wt. % to about 0.09 wt. % based on a total weight of the polishing composition.

The polishing composition can further optionally include low surface tension defoamers and air-release agents. The defoamer can be any suitable anti-foaming agent, such as, but not limited to e.g. silicon-based, siloxanes, acetylenic diol-based, insoluble oils like mineral oil, polymethylsiloxanes and other silicones, alcohols in the likes of ethanol, methanol, isopropanol, butanol, cyclohexanol, stearates, hydrophobic polyols, hydrophobic silica, ethylene-bis-stearamide, fatty acids, fatty acid alcohols, and glycol defoamers. The concentration of defoamers in the polishing composition typically is from about 1 parts per million (ppm) to about 10 ppm, from about 1 ppm to about 20 ppm, from about 1 ppm to about 30 ppm, from about 1 ppm to about 40 ppm, from about 1 ppm to about 50 ppm, from about 1 ppm to about 60 ppm, from about 1 ppm to about 70 ppm, from about 1 ppm to about 80 ppm, from about 1 ppm to about 90 ppm, from about 1 ppm to about 100 ppm, from about 1 ppm to about 110 ppm, from about 1 ppm to about 120 ppm, from about 1 ppm to about 130 ppm, from about 1 ppm to about 140 ppm, from about 1 ppm to about 150 ppm, from about 10 ppm to about 150 ppm, from about 20 ppm to about 150 ppm, from about 30 ppm to about 150 ppm, from about 40 ppm to about 150 ppm, from about 50 ppm to about 150 ppm, from about 60 ppm to about 150 ppm, from about 70 ppm to about 150 ppm, from about 80 ppm to about 150 ppm, from about 90 ppm to about 150 ppm, from about 100 ppm to about 150 ppm, from about 110 ppm to about 150 ppm, from about 120 ppm to about 150 ppm, from about 130 ppm to about 150 ppm, from about 140 ppm to about 150 ppm, from about 10 ppm to about 20 ppm, from about 15 ppm to about 20 ppm, from about 20 ppm to about 25 ppm, from about 20 ppm to about 30 ppm, from about 25 ppm to about 30 ppm, from about 30 ppm to about 35 ppm, from about 30 ppm to about 40 ppm, from about 10 ppm to about 40 ppm, from about 15 ppm to about 40 ppm, from about 20 ppm to about 40 ppm, from about 25 ppm to about 40 ppm, from about 40 ppm to about 50 ppm, from about 45 ppm to about 50 ppm, from about 50 ppm to about 60 ppm, from about 55 ppm to about 60 ppm, from about 60 ppm to about 70 ppm, from about 65 ppm to about 70 ppm, from about 40 ppm to about 70 ppm, from about 45 ppm to about 70 ppm, from about 50 ppm to about 70 ppm, from about 55 ppm to about 70 ppm, from about 70 ppm to about 80 ppm, from about 75 ppm to about 80 ppm, from about 80 ppm to about 90 ppm, from about 85 ppm to about 90 ppm, from about 90 ppm to about 100 ppm, from about 70 ppm to about 100 ppm, from about 75 ppm to about 100 ppm, or from about 80 ppm to about 100 ppm.

An oxidizing agent may also optionally be used, which may be selected from the group consisting of hydrogen peroxide, oxone, ammonium cerium nitrate, periodates, iodates, persulfates, and mixtures thereof. The periodates, iodates, and persulfates can be any periodate, iodate, persulfate, or combination of periodates, iodates, and persulfates, such as e.g. potassium periodate, potassium iodate, ammonium persulfate, potassium persulfate, or sodium persulfate. In some examples, the oxidizing agent is oxone or potassium persulfate. The oxidizing agent can be present in the polishing composition in any suitable amount that is not inconsistent and incompatible with the objectives of the present subject matter. Typically, the polishing composition may include about 0.001 wt. % or more, e.g., about 0.005 wt. % or more, about 0.01 wt. % or more, about 0.05 wt. % or more, or about 0.1 wt. % or more of the oxidizing agent. In some examples, the polishing composition may include about 20 wt. % or less, e.g., about 17 wt. % or less, about 15 wt. % or less, about 12 wt. % or less, about 10 wt. % or less, about 7 wt. % or less, about 5 wt. % or less, about 2 wt. % or less, or about 0.5 wt. % or less of the oxidizing agent. In other examples, the polishing composition may include from about 0.001 wt. % to about 20 wt. %, e.g., from about 0.001 wt. % to about 17 wt. %, from about 0.001 wt. % to about 15 wt. %, from about 0.001 wt. % to about 12 wt. %, from about 0.001 wt. % to about 10 wt. %, from about 0.001 wt. % to about 7 wt. %, from about 0.001 wt. % to about 5 wt. %, from about 0.001 wt. % to about 2 wt. %, from about 0.005 wt. % to about 20 wt. %, from about 0.005 wt. % to about 17 wt. %, from about 0.005 wt. % to about 15 wt. %, from about 0.005 wt. % to about 12 wt. %, from about 0.005 wt. % to about 10 wt. %, from about 0.005 wt. % to about 7 wt. %, from about 0.005 wt. % to about 5 wt. %, from about 0.005 wt. % to about 2 wt. %, 0.01 wt. % to about 20 wt. %, 0.01 wt. % to about 17 wt. %, from about 0.01 wt. % to about 15 wt. %, from about 0.01 wt. % to about 12 wt. %, from about 0.01 wt. % to about 10 wt. %, from about 0.01 wt. % to about 7 wt. %, from about 0.01 wt. % to about 5 wt. %, 0.01 wt. % to about 2 wt. %, from about 0.05 wt. % to about 20 wt. %, from about 0.05 wt. % to about 17 wt. %, from about 0.05 wt. % to about 15 wt. %, from about 0.05 wt. % to about 10 wt. %, from about 0.05 wt. % to about 7 wt. %, from about 0.05 wt. % to about 5 wt. %, from about 0.05 wt. % to about 2 wt. %. In still other examples, the polishing composition may include from about 0.001 wt. % to about 0.05 wt. %, from about 0.001 wt. % to about 0.1 wt. %, 0.001 wt. % to about 0.2 wt. %, 0.001 wt. % to about 0.3 wt. %, 0.001 wt. % to about 0.4 wt. %, from about 0.001 wt. % to about 0.5 wt. %, 0.001 wt. % to about 0.6 wt. %, 0.001 wt. % to about 0.7 wt. %, 0.001 wt. % to about 0.8 wt. %, 0.001 wt. % to about 0.9 wt. %, or from about 0.001 wt. % to about 1 wt. % of the oxidizing agent based on a total weight of the polishing composition.

The polishing composition disclosed herein may exhibit any suitable pH that is not inconsistent and incompatible with the scope of the present subject matter. In some examples, the polishing composition can typically have a pH spanning a range from about 3 to about 11. Without wishing to be bound by any particular theory, the polishing-rate of the inventive compositions may increase, as the pH is lowered from for instance 11 to 3. Therefore, in some examples, the polishing composition may have a pH ranging from about 3 to about 11, from about 3 to about 10, from about 3 to about 9, from about 3 to about 8, from about 3 to about 7, from about 3 to about 6, from about 3 to about 5, from about 3 to about 4, or however alternatively, a pH spanning a range from about 4 to about 11, from about 5 to about 11, from about 6 to about 11, from about 7 to about 11, from about 8 to about 11, from about 9 to about 11, from about 10 to about 11, from about 4 to about 10, from about 5 to about 10, from about 6 to about 10, from about 7 to about 10, from about 8 to about 10, from about 9 to about 10, from about 4 to about 9, from about 5 to about 9, from about 6 to about 9, from about 7 to about 9, from about 8 to about 9, from about 4 to about 8, from about 5 to about 8, from about 6 to about 8, from about 7 to about 8, from about 4 to about 7, from about 5 to about 7, from about 6 to about 7, from about 4 to about 6, or from about 5 to about 6.

If desired, to achieve the foregoing pH-levels, a pH-adjuster, or a pH buffering agent, or a combination thereof may be utilized. Any suitable pH-adjuster can be included in the polishing composition. By way of example, the pH-adjuster can be in the form of for instance one or more of nitric acid, sulfuric acid, hydrochloric acid, phosphoric acid, or any combinations thereof, or in the form of a base in the likes of for example sodium hydroxide, potassium hydroxide, cesium hydroxide, or ammonium hydroxide, or any combinations thereof. The pH buffering agent can be any suitable buffering agent, for example, phosphates, acetates, borates, sulfonates, carboxylates, ammonium salts, and the like, or any combinations thereof. The pH-adjuster, or the pH buffering agent may typically be included in an amount effective to achieve a desired pH-level, such as, in an amount of from about 0.001 wt. % to about 20 wt. %, e.g., from about 0.001 wt. % to about 17 wt. %, from about 0.001 wt. % to about 15 wt. %, from about 0.001 wt. % to about 12 wt. %, from about 0.001 wt. % to about 10 wt. %, from about 0.001 wt. % to about 7 wt. %, from about 0.001 wt. % to about 5 wt. %, from about 0.001 wt. % to about 2 wt. %, from about 0.005 wt. % to about 20 wt. %, from about 0.005 wt. % to about 17 wt. %, from about 0.005 wt. % to about 15 wt. %, from about 0.005 wt. % to about 12 wt. %, from about 0.005 wt. % to about 10 wt. %, from about 0.005 wt. % to about 7 wt. %, from about 0.005 wt. % to about 5 wt. %, from about 0.005 wt. % to about 2 wt. %, 0.01 wt. % to about 20 wt. %, 0.01 wt. % to about 17 wt. %, from about 0.01 wt. % to about 15 wt. %, from about 0.01 wt. % to about 12 wt. %, from about 0.01 wt. % to about 10 wt. %, from about 0.01 wt. % to about 7 wt. %, from about 0.01 wt. % to about 5 wt. %, 0.01 wt. % to about 2 wt. %, from about 0.05 wt. % to about 20 wt. %, from about 0.05 wt. % to about 17 wt. %, from about 0.05 wt. % to about 15 wt. %, from about 0.05 wt. % to about 10 wt. %, from about 0.05 wt. % to about 7 wt. %, from about 0.05 wt. % to about 5 wt. %, from about 0.05 wt. % to about 2 wt. %, from about 0.001 wt. % to about 0.05 wt. %, from about 0.001 wt. % to about 0.1 wt. %, 0.001 wt. % to about 0.2 wt. %, 0.001 wt. % to about 0.3 wt. %, 0.001 wt. % to about 0.4 wt. %, from about 0.001 wt. % to about 0.5 wt. %, 0.001 wt. % to about 0.6 wt. %, 0.001 wt. % to about 0.7 wt. %, 0.001 wt. % to about 0.8 wt. %, 0.001 wt. % to about 0.9 wt. %, or from about 0.001 wt. % to about 1 wt. % based on a total weight of the polishing composition.

The polishing composition may ideally further include polymers in the likes of non-limiting examples, such as, e.g. polyvinylchloride, polyvinylfluoride, polyvinyl alcohol, polyvinyl acetate, vinyl polymer, polyvinylkpyrrolidone, fluorocarbon, polycarbonate, fluoropolymer, polycarbonate, polyester, polyacrylate, polyether, polyethylene, polyamide, polyurethane, polystyrene, polypropylene, polyvinylfluoride, urethane, copolymers of nonionic monomers and ethylenically unsaturated monomers containing moieties, such as acryloylalkyl trialkyl ammonium salts e.g. acryloylethyl trimethyl ammonium chloride, methacryloylalkyl trialkyl ammonium salts e.g. methacryloylethyl trimethyl ammonium chloride, acrylamido- and methacrylamidoalkyl trialkyl ammonium salts e.g., acrylamidopropyl trimethyl ammonium chloride and methacrylamidopropyl trimethyl ammonium chloride, and polymers including sulfonic acid monomeric units, referred to hereinafter as a sulfonic acid polymer or copolymer. The sulfonic acid monomeric units can be any suitable sulfonic acid monomeric units including one or more groups of the formula: —SO₃H. Non-limiting examples of suitable sulfonic acid (homo) polymers include polyvinylsulfonic acid, polystyrenesulfonic acid (e.g., poly(4-styrenesulfonic acid)), polyallylsulfonic acid, poly ethyl acrylate sulfonic acid, poly butyl acrylate sulfonic acid, poly isoprenesulfonic acid, and the like. Suitable sulfonic acid copolymers include copolymers including sulfonic acid monomeric units and monomers including carboxylic acid groups, or derivatives of carboxylic acid groups such as amides.

The polishing composition can include about 1 ppm or more of the polymers, e.g., about 5 ppm or more, about 10 ppm or more, about 20 ppm or more, about 30 ppm or more, about 40 ppm or more, or about 50 ppm or more. Alternatively, or in addition, the polishing composition can include about 500 ppm or less of the polymers, e.g., about 450 ppm or less, about 400 ppm or less, about 350 ppm or less, about 300 ppm or less, about 250 ppm or less, about 200 ppm or less, about 150 ppm or less, or about 100 ppm or less. Thus, the polishing composition can include the polymers in an amount bounded by any two of the aforementioned endpoints. For example, the polishing composition can include about 1 ppm to about 500 ppm of the polymers, about 5 ppm to about 450 ppm, about 10 ppm to about 400 ppm, about 10 ppm to about 350 ppm, about 10 ppm to about 300 ppm, about 10 ppm to about 250 ppm, about 10 ppm to about 200 ppm, about 20 ppm to about 300 ppm, about 20 ppm to about 250 ppm, about 20 ppm to about 200 ppm, about 20 ppm to about 150 ppm, about 20 ppm to about 100 ppm, about 10 ppm to about 100 ppm, about 10 ppm to about 90 ppm, about 10 ppm to about 80 ppm, about 10 ppm to about 70 ppm, about 10 ppm to about 60 ppm, about 10 ppm to about 50 ppm, or about 10 ppm to about 40 ppm.

Biocides as known in the art may also be incorporated into the polishing composition in some examples. The biocide can be any suitable biocide, as would be known to one of ordinary skill in the art and can be present in the polishing composition in any suitable amount that is not inconsistent and incompatible with the principles of the present subject matter. By way of example and without limitation, a suitable biocide may be an isothuazolinone biocide, isothiazolinone, or like biocides, alcohols, aldehydes, chlorine, and chlorine-releasing agents e.g., sodium hypochlorite, chlorhexidine, iodine, peroxygen compounds e.g., hydrogen peroxide, peracetic acid, phenolic type compounds, quaternary ammonium compounds e.g. benzalkonium chloride, bases e.g. sodium hydroxide, potassium hydroxide, and acids e.g. mineral and organic acids. A concentration of the biocide used in the polishing composition typically can be from about 1 ppm to about 60 ppm, from about 1 ppm to about 50 ppm, from about 1 ppm to about 40 ppm, from about 1 ppm to about 30 ppm, from about 1 ppm to about 20 ppm, from about 1 ppm to about 10 ppm, from about 1 ppm to about 5 ppm, from about 10 ppm to about 60 ppm, from about 15 ppm to about 60 ppm, from about 20 ppm to about 60 ppm, from about 25 ppm to about 60 ppm, from about 30 ppm to about 60 ppm, from about 35 ppm to about 60 ppm, from about 40 ppm to about 60 ppm, from about 45 ppm to about 60 ppm, from about 50 ppm to about 60 ppm, or from about 55 ppm to about 60 ppm.

The polishing composition can also include conventional rheology modifiers in the likes of e.g., castor oil derivative polymers, cellulose, alkali-acrylic emulsions, hydrophobic ethoxylated urethane resins, polyurea, polyamides, calcium sulfonates, and such similar and equivalent rheology modifiers, in a concentration generally ranging from about 1000 ppm to about 20000 ppm. In some examples, the polishing composition includes from about 2500 ppm to about 20000 ppm of the rheology modifier. In other examples, the polishing composition includes from about 5000 ppm to about 20000 ppm of the rheology modifier. In still other examples, the polishing composition includes from about 7500 ppm to about 20000 ppm of the rheology modifier. In yet other examples, the polishing composition includes from about 10000 ppm to about 20000 ppm of the rheology modifier. In further other examples, the polishing composition includes from about 12500 ppm to about 20000 ppm of the rheology modifier. In even other examples, the polishing composition includes from about 15000 ppm to about 20000 ppm of the rheology modifier. In even further other examples, the polishing composition includes from about 17500 ppm to about 20000 ppm of the rheology modifier.

The polishing composition may also include from about 1000 ppm to about 2500 ppm, from about 2500 ppm to about 5000 ppm, from about 5000 ppm to about 7500 ppm, from about 1000 ppm to about 7500 ppm, from about 2000 ppm to about 7500 ppm, from about 2500 ppm to about 7500 ppm, from about 3000 ppm to about 7500 ppm, from about 4000 ppm to about 7500 ppm, from about 5000 ppm to about 7500 ppm, from about 6000 ppm to about 7500 ppm, from about 7000 ppm to about 7500 ppm, from about 7500 ppm to about 10000 ppm, from about 8500 ppm to about 10000 ppm, from about 9500 ppm to about 10000 ppm, from about 10000 ppm to about 12500 ppm, from about 10000 ppm to about 13000 ppm, from about 11000 ppm to about 12500 ppm, from about 11500 ppm to about 12500 ppm, from about 12000 ppm to about 12500 ppm, from about 12500 ppm to about 15000 ppm, from about 13000 ppm to about 15000 ppm, from about 13500 ppm to about 15000 ppm, from about 14000 ppm to about 15000 ppm, from about 15000 ppm to about 17500 ppm, from about 16000 ppm to about 17500 ppm, from about 16500 ppm to about 17500 ppm, from about 10000 ppm to about 15000 ppm, from about 10500 ppm to about 15000 ppm, from about 11000 ppm to about 15000 ppm, from about 11500 ppm to about 15000 ppm, from about 12000 ppm to about 15000 ppm, from about 10000 ppm to about 17500 ppm, from about 10500 ppm to about 17500 ppm, from about 11000 ppm to about 17500 ppm, from about 11500 ppm to about 17500 ppm, from about 12000 ppm to about 17500 ppm, from about 12500 ppm to about 17500 ppm, from about 13000 ppm to about 17500 ppm, from about 13500 ppm to about 17500 ppm, from about 14000 ppm to about 17500 ppm, from about 14500 ppm to about 17500 ppm, from about 15000 ppm to about 17500 ppm, from about 15500 ppm to about 17500 ppm, from about 16000 ppm to about 17500 ppm, from about 16500 ppm to about 17500 ppm, or from about 17000 ppm to about 17500 ppm of the rheology modifier.

The polishing composition may optionally further include a chelating, or a complexing agent. The complexing agent may be any suitable chemical additive that enhances the material removal rate from the semiconductor wafer surface, or that removes trace metal contaminants during the polishing cycle. Suitable chelating, or complexing agents can include, for example, carbonyl compounds e.g., acetylacetonates and the like, simple carboxylates e.g., acetates, aryl carboxylates, and the like, carboxylates containing one or more hydroxyl groups e.g., glycolates, lactates, gluconates, gallic acid and salts, or partial salts thereof, and the like, di-, tri-, and poly-carboxylates e.g., oxalates, oxalic acid, phthalates, citrates, succinates, tartrates, malates, edetates e.g., dipotassium EDTA, mixtures thereof, and the like, carboxylates containing one or more sulfonic and/or phosphonic groups, and the like. Suitable chelating or complexing agents also can include, for example, di-, tri-, or polyalcohols e.g., ethylene glycol, pyrocatechol, pyrogallol, tannic acid, and the like, polyphosphonates, such as Dequest 2010, Dequest 2060, or Dequest 2000 (available from Solutia Corp.), and amine-containing compounds e.g., ammonia, amino acids, amino alcohols, di-, tri-, and polyamines, and the like in an amount of from about 0.001 wt. % to about 20 wt. %, e.g., from about 0.001 wt. % to about 17 wt. %, from about 0.001 wt. % to about 15 wt. %, from about 0.001 wt. % to about 12 wt. %, from about 0.001 wt. % to about 10 wt. %, from about 0.001 wt. % to about 7 wt. %, from about 0.001 wt. % to about 5 wt. %, from about 0.001 wt. % to about 2 wt. %, from about 0.005 wt. % to about 20 wt. %, from about 0.005 wt. % to about 17 wt. %, from about 0.005 wt. % to about 15 wt. %, from about 0.005 wt. % to about 12 wt. %, from about 0.005 wt. % to about 10 wt. %, from about 0.005 wt. % to about 7 wt. %, from about 0.005 wt. % to about 5 wt. %, from about 0.005 wt. % to about 2 wt. %, 0.01 wt. % to about 20 wt. %, 0.01 wt. % to about 17 wt. %, from about 0.01 wt. % to about 15 wt. %, from about 0.01 wt. % to about 12 wt. %, from about 0.01 wt. % to about 10 wt. %, from about 0.01 wt. % to about 7 wt. %, from about 0.01 wt. % to about 5 wt. %, 0.01 wt. % to about 2 wt. %, from about 0.05 wt. % to about 20 wt. %, from about 0.05 wt. % to about 17 wt. %, from about 0.05 wt. % to about 15 wt. %, from about 0.05 wt. % to about 10 wt. %, from about 0.05 wt. % to about 7 wt. %, from about 0.05 wt. % to about 5 wt. %, from about 0.05 wt. % to about 2 wt. %, from about 0.001 wt. % to about 0.05 wt. %, from about 0.001 wt. % to about 0.1 wt. %, 0.001 wt. % to about 0.2 wt. %, 0.001 wt. % to about 0.3 wt. %, 0.001 wt. % to about 0.4 wt. %, from about 0.001 wt. % to about 0.5 wt. %, 0.001 wt. % to about 0.6 wt. %, 0.001 wt. % to about 0.7 wt. %, 0.001 wt. % to about 0.8 wt. %, 0.001 wt. % to about 0.9 wt. %, or from about 0.001 wt. % to about 1 wt. % based on a total weight of the polishing composition.

The polishing composition disclosed herein can be prepared by any suitable technique, many of which are readily known to those skilled in the art. The polishing composition may be prepared in a batch, a continuous process, or a combination thereof.

It will be understood that, generally, the actual quantity of one or more ingredients in the polishing compositions in accordance with embodiments of the disclosure e.g., diamond particles, polishing composition components, and water may vary depending on the desired degree of dilution or concentration. In this aspect, some embodiments can be packaged in the form of a concentrate e.g., a 50-times concentrate, a 100-times concentrate, a 200-times concentrate, etc., where water can later be added, in order to dilute the polishing composition, such as at a point of use e.g., by an end-user. Alternatively, the polishing composition can be packaged in a diluted form with water already included. For example, in some embodiments, the concentrated forms of each ingredient of the polishing composition, as a whole, can facilitate ease of shipping, distribution, and sale. However in other embodiments, each ingredient of the polishing composition, as a whole, can be in a diluted form, e.g., to simplify end-use by the user. Thus, the weight ranges for ingredients as set forth herein can refer to either the diluted, or concentrated ranges.

Accordingly, each ingredient can be present in a diluted form that is suitable for end-use, or in a form that is concentrated when received, and then subsequently diluted when in use by the end-user, e.g. concentrated 2-times, concentrated 5-times, concentrated 10-times, concentrated 25-times, concentrated 40-times, concentrated 50-times, concentrated 60-times, concentrated 70-times, concentrated 100-times, concentrated 125-times, concentrated 150-times, concentrated 175-times, concentrated 200-times. When the concentrate is diluted with water, e.g. 1 weight of water, 4 weight of water, 9 weight of water, 24 weight of water, 39 weight of water, 49 weight of water, 59 weight water, 69 weight of water, 99 weight of water, 124 weight of water, 149 weight of water, 174 weight of water, 199 weight of water respectively, each ingredient of the polishing composition will be present in embodiments of the subject matter in an amount within the diluted ranges. Furthermore, as will be understood by those of ordinary skill in the art, the concentrate can contain an appropriate fraction of the water being present in the final solution. For example, in some applications, the concentrate can contain a suitable fraction of the water being present in the final polishing composition, in order to ensure that the polishing composition components are at least partially, or fully dissolved in the concentrated form.

### Methods for Polishing a Surface of a Semiconductor Wafer

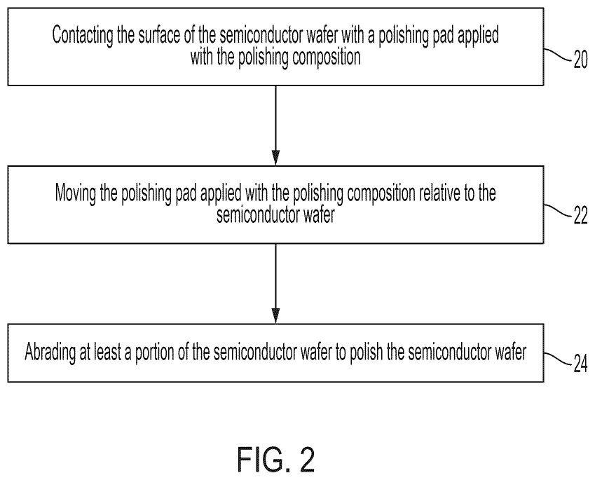

The subject matter of the current disclosure also provides a method for polishing a surface of a semiconductor wafer, which process, is depicted in FIG. 2. Drawing the attention of the reader to FIG. 2, the process includes at least the steps of contacting the surface of a semiconductor wafer with a polishing pad applied with the aforementioned polishing composition in step 20. The polishing pad applied with the forementioned polishing composition is next moved relative to the semiconductor wafer in step 22. Finally, the method is concluded by at least a portion of the semiconductor wafer being abraded, so as to polish the semiconductor wafer as demonstrated in step 24.

A person having ordinary skill in the art would know that this can routinely be performed on for example a 15″ bench top lapping polishing machine (Lapmaster Wolters) in typically a single-sided polishing configuration applied on the semiconductor wafer surface. Alternatively, in other examples, the polishing of the semiconductor wafer surface can suitably also be performed by using a double-sided polishing configuration.

Generally speaking, such a lapping polishing apparatus contains a platen, which platen, when in use, is in motion and has a velocity that results from orbital, linear, or circular motion. A polishing pad is in direct contact with the platen, and thus moving with the platen when the platen has been put into motion. A carrier holds the semiconductor wafer to be polished by contacting and moving the semiconductor wafer relative to the surface of the polishing pad. The polishing of the semiconductor wafer is performed by placing the semiconductor wafer in contact with the polishing pad and the polishing composition (i.e. which polishing composition being disposed between the semiconductor wafer and the polishing pad), while the polishing pad and the platen together move in a relative configuration to the semiconductor wafer, so as to abrade at least a portion of the semiconductor wafer.

The degree of the polishing end point is determined by monitoring the weight of the semiconductor wafer, which is used to compute the amount of material that is abraded, and thereby removed from the semiconductor wafer. Such techniques are routinely well known in the art by a person having ordinary skill in the art.

Polishing refers to the removal of at least a portion of a surface of the semiconductor wafer to polish the surface. Polishing can be performed to provide a semiconductor wafer surface having a reduced surface roughness when polishing is complete by removing for example gouges, crates, pits, and the like. However, alternatively polishing also can be performed to introduce, or to restore a surface-geometry characterized by an intersection of planar-segments.

The polishing pad can ideally be made of any suitable material or configuration, many of which are known readily in the art by a person having ordinary skill in the art. Suitable polishing pads may for example include without limitation woven and non-woven polishing pads. Moreover, suitable polishing pads can be made of any suitable polymer of varying density, hardness, thickness, compressibility, ability to rebound upon compression, and compression modulus. Such suitable polymers may typically include, for example the following choices but without limitation, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and any mixtures or combinations thereof.

The polishing pad can typically assume any suitable configuration to impart an effective polishing-cycle to the semiconductor wafer surface. For example, the polishing pad can be circular and, when in use, typically may have a rotational motion about an axis perpendicular to the plane defined by the surface of the pad. The polishing pad can be cylindrical, the surface of which acts as the polishing surface, and when in use, typically may exhibit a rotational motion about the central axis of the cylinder. The polishing pad can be in the form of an endless belt, which, when in use, typically may display a linear motion with respect to the cutting edge being polished. The polishing pad can readily assume any suitable shape and, when in use, may have a reciprocating, or orbital motion along a plane or a semicircle. Many other variations and configurations will be readily apparent and available to a person having ordinary skill in the art, and are thus likewise intended to be incorporated and covered by the scope of the present disclosure.

It should be emphasized that the method of the present subject matter may routinely be used to polish any suitable semiconductor wafer surface. In some examples, this may particularly include polishing at least one layer of silicon carbide (SiC) from for example a SiC wafer surface with a polishing composition having therein a surface-modified monocrystalline diamond in accordance with the core principles of the present subject matter. In some examples, the SiC may be monocrystalline SiC. The SiC can be removed from the surface at any suitable rate to ultimately effect polishing of the SiC wafer surface. For example, the SiC can be removed at a rate ranging from about 1.3 μm/hr to about 8.2 μm/hr. In some examples, the SiC is removed at a rate ranging from about 2.2 μm/hr to about 8.2 μm/hr. In other examples, the SiC is removed at a rate ranging from about 3.2 μm/hr to about 8.2 μm/hr. In still other examples, the SiC is removed at a rate ranging from about 4.2 μm/hr to about 8.2 μm/hr. In yet other examples, the SiC is removed at a rate ranging from about 5.2 μm/hr to about 8.2 μm/hr. In even other examples, the SiC is removed at a rate ranging from about 6.2 μm/hr to about 8.2 μm/hr. In further even other examples, the SiC is removed at a rate ranging from about 7.2 μm/hr to about 8.2 μm/hr.

The SiC may also be removed at a rate ranging from about 1.3 μm/hr to about 2.2 μm/hr, ranging from about 2.2 μm/hr to about 3.2 μm/hr, ranging from about 3.2 μm/hr to about 4.2 μm/hr, ranging from about 1.3 μm/hr to about 4.2 μm/hr, ranging from about 2.2 μm/hr to about 4.2 μm/hr, ranging from about 3.2 μm/hr to about 4.2 μm/hr, ranging from about 4.2 μm/hr to about 5.2 μm/hr, ranging from about 4.2 μm/hr to about 6.2 μm/hr, ranging from about 4.2 μm/hr to about 7.2 μm/hr, ranging from about 5.2 μm/hr to about 6.2 μm/hr, ranging from about 6.2 μm/hr to about 7.2 μm/hr, ranging from about 1.3 μm/hr to about 3.3 μm/hr, ranging from about 1.3 μm/hr to about 7.2 μm/hr, ranging from about 3.3 μm/hr to about 7.2 μm/hr, or ranging from about 3.3 μm/hr to about 8.2 μm/hr.

A material removal rate of the SiC may be increased by a range of from about 185% to about 245% with the polishing composition having therein the surface-modified monocrystalline diamond 10, when compared to a polishing composition including monocrystalline diamond particles or polycrystalline diamond particles. In some examples, the material removal rate of the SiC is increased by a range of from about 190% to about 245% with the polishing composition having therein the surface-modified monocrystalline diamond 10, when compared to a polishing composition including monocrystalline diamond particles or polycrystalline diamond particles. In yet other examples, the material removal rate of the SiC is increased by a range of from about 200% to about 245% with the polishing composition having therein the surface-modified monocrystalline diamond 10, when compared to a polishing composition including monocrystalline diamond particles or polycrystalline diamond particles. In even other examples, the material removal rate of the SiC is increased by a range of from about 210% to about 245% with the polishing composition having therein the surface-modified monocrystalline diamond 10, when compared to a polishing composition including monocrystalline diamond particles or polycrystalline diamond particles. In further other examples, the material removal rate of the SiC is increased by a range of from about 220% to about 245% with the polishing composition having therein the surface-modified monocrystalline diamond 10, when compared to a polishing composition including monocrystalline diamond particles or polycrystalline diamond particles. In even further other examples, the material removal rate of the SiC is increased by a range of from about 230% to about 245% with the polishing composition having therein the surface-modified monocrystalline diamond 10, when compared to a polishing composition including monocrystalline diamond particles or polycrystalline diamond particles.

The material removal rate of the SiC may also be increased by a range of from about 185% to about 190%, from about 190% to about 195%, from about 185% to about 195%, from about 185% to about 200%, from about 185% to about 205%, from about 185% to about 210%, from about 185% to about 215%, from about 185% to about 220%, from about 185% to about 225%, from about 185% to about 230%, from about 185% to about 235%, from about 185% to about 240%, from about 190% to about 200%, from about 190% to about 205%, from about 190% to about 210%, from about 190% to about 215%, from about 190% to about 220%, from about 190% to about 225%, from about 190% to about 230%, from about 190% to about 235%, from about 190% to about 240%, from about 195% to about 200%, from about 195% to about 205%, from about 195% to about 210%, from about 195% to about 215%, from about 195% to about 220%, from about 195% to about 225%, from about 195% to about 230%, from about 195% to about 235%, from about 195% to about 240%, from about 195% to about 245%, from about 200% to about 205%, from about 200% to about 210%, from about 200% to about 215%, from about 210% to about 220%, from about 210% to about 225%, from about 210% to about 230%, from about 210% to about 235%, from about 210% to about 240%, from about 200% to about 220%, from about 200% to about 225%, from about 200% to about 230%, from about 200% to about 235%, from about 215% to about 220%, from about 220% to about 225%, from about 220% to about 230%, from about 220% to about 235%, from about 220% to about 240%, from about 225% to about 230%, from about 220% to about 235%, from about 225% to about 235%, from about 225% to about 240%, from about 230% to about 240%, from about 225% to about 245%, from about 235% to about 240%, from about 235% to about 245%, or from about 240% to about 245% with the polishing composition having therein the surface-modified monocrystalline diamond 10, when compared to a polishing composition including monocrystalline diamond particles or polycrystalline diamond particles.

### EXAMPLE

The following example is put forth so as to provide those of ordinary skill in the art with a complete disclosure and description of how to make and use the described subject matter and is not intended to limit the scope of what the inventors regard as their disclosure, and nor is it intended to represent that the experiment below is all, or the only experiment performed. Efforts have been made to ensure accuracy with respect to numbers used, but some experimental errors and deviations should be accounted for.

### Example 1

Polishing Compositions Including a Surface-Modified Monocrystalline Diamond Exhibit Improved Silicon Carbide (SiC) Removal Rates from the Surface of SiC Wafers when Compared to Polishing Compositions Including Monocrystalline Diamond Particles or Polycrystalline Diamond Particles

Material removal rates of silicon carbide (SiC) from a surface of a 4-inch diameter silicon carbide wafer, and a surface roughness were tested by using either (I) a polishing composition employing a surface-modified monocrystalline diamond (Smmd* in TABLE 1) with a D(50) particle size characterized as being 0.25 μm, 0.5 μm, 0.75 μm, or 1 μm; (II) a polishing composition employing monocrystalline diamond (Mono in TABLE 1) with a D(50) particle size particle size characterized as being 0.25 μm, 0.5 μm, 0.75 μm, or 1 μm; or (III) a polishing composition employing polycrystalline diamond (Poly in TABLE 1) with a D(50) particle size particle size characterized as being 0.25 μm, 0.5 μm, 0.75 μm, or 1 μm, in accordance with an exemplary embodiment of the present subject matter. All the chemical constituents of the polishing compositions of (I), (II), and (III) were the same, except for the used particular diamond-type.

TABLE 1 shows the particle size of the used diamond in the polishing composition in column 1, the particular diamond-type used in the polishing composition in column 2, and the obtained results for the material removal rates of SiC from the SiC wafer surface in column 3, the surface roughness of the SiC wafer in column 4, the mean value by volume distribution in column 5, the D(50) particle size distribution in column 6, and the D(99) particle size distribution in column 7. All the demonstrated polishing data shown in TABLE 1 was obtained on a 15″ bench top lapping polishing machine (Lapmaster Wolters) by using a 15″ polishing pad made of polyurethane. The platen of the 15″ bench top lapping polishing machine was subjected to a circular motion defined by 60 revolutions per minute (RPM), and the diamond slurries were applied at a slurry flow rate of 10 mL/min with a 3.2 psi down force. Diamond particles were used at a concentration of 80 carats/gallon in the polishing compositions (I), (II), and (III) as a water-based slurry suspended in distilled water (DIW). The obtained results were the following.

Essentially, polishing compositions including the surface-modified monocrystalline diamond (Smmd* in TABLE 1) exhibited a material removal rate of SiC from the SiC wafer surface, which was increased by a range of from about from 185% to about 245%, when compared to a polishing composition including either monocrystalline diamond particles (Mono in TABLE 1) or polycrystalline diamond particles (Poly in TABLE 1).

To obtain the foregoing results, the calculated average value of the material removal rate in column 3 for each particle size of respectively 0.25 μm, 0.5 μm, 0.75 μm, or 1 μm for the monocrystalline diamond (Mono in TABLE 1) and the polycrystalline diamond (Poly in TABLE 1) was compared to its corresponding respective surface-modified monocrystalline diamond (Smmd* in TABLE 1) value used at the same diamond particle size. In other words, the average calculated value of the material removal rate in column 3 for Mono 0.25 μm and for Poly 0.25 μm was compared to the material removal rate value of the surface-modified monocrystalline diamond (Smmd) 0.25 μm*. The average calculated value of the material removal rate in column 3 for Mono 0.50 μm and for Poly 0.50 μm was compared to the material removal rate value of the surface-modified monocrystalline diamond (Smmd) 0.50 μm*. The average calculated value of the material removal rate in column 3 for Mono 0.75 μm and for Poly 0.75 μm was compared to the material removal rate value of the surface-modified monocrystalline diamond (Smmd) 0.75 μm*. The average calculated value of the material removal rate in column 3 for Mono 1 μm and for Poly 1 μm was compared to the material removal rate value of the surface-modified monocrystalline diamond (Smmd) 1 μm*.

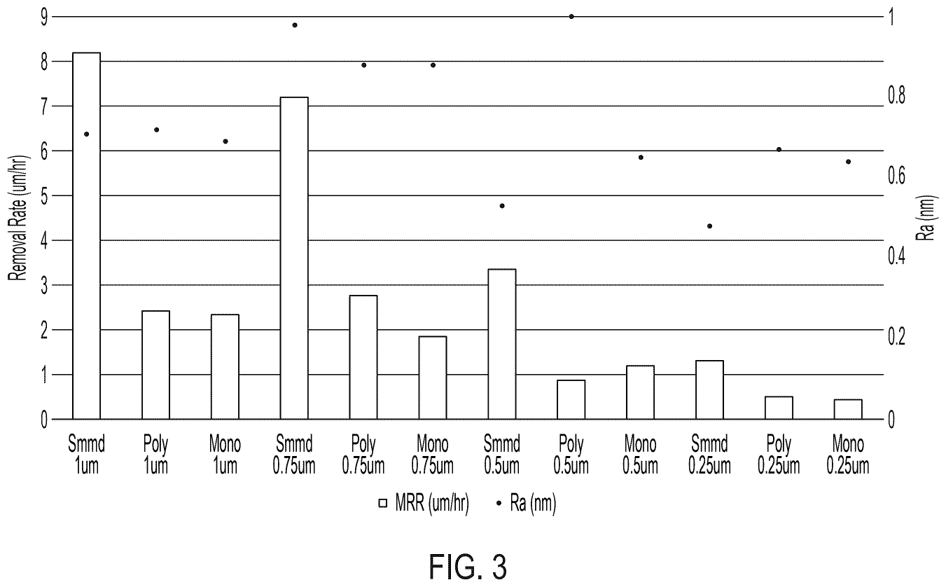

The results of TABLE 1 are further shown graphically in FIG. 3. Importantly, what is noteworthy is that the measured surface roughness is substantially similar or improved when polishing with the surface-modified monocrystalline diamond (Smmd* in TABLE 1), in comparison to the monocrystalline diamond (Mono in TABLE 1) or the polycrystalline diamond (Poly in TABLE 1), as illustrated with the black closed dots, where the obtained surface roughness values are viewed on the right-hand side y-axis in FIG. 3.

TABLE 1

| | | | 3. | | | | |
|---|---|---|---|---|---|---|---|
| | | 2. | Material | 4. | 5. | | |
| 1. | | Diamond-type | Removal | Surface | Volume | 6. | 7. |
| Particle | | in polishing | Rate | Roughness | Distribution | D(50) | D(99) |
| Size | | composition | (um/hr) | (nm) | (um) | (um) | (um) |
| 1 | um | Smmd 1 μm* | 8.2 | 0.71 | 1.3 | 1.08 | 7.01 |
| | | Poly 1 μm | 2.4 | 0.72 | 1.09 | 0.97 | 3.71 |
| | | Mono 1 μm | 2.34 | 0.69 | 0.92 | 0.86 | 2.21 |
| 0.75 | um | Smmd 0.75 μm* | 7.2 | 0.98 | 0.9 | 0.79 | 3.35 |
| | | Poly 0.75 μm | 2.76 | 0.88 | 0.86 | 0.79 | 2.23 |
| | | Mono 0.75 μm | 1.84 | 0.88 | 0.79 | 0.75 | 1.63 |
| 0.5 | um | Smmd 0.5 μm* | 3.34 | 0.53 | 0.59 | 0.56 | 1.16 |
| | | Poly 0.5 μm | 0.84 | 1 | 0.59 | 0.55 | 1.3 |
| | | Mono 0.5 μm | 1.18 | 0.65 | 0.4 | 0.38 | 0.87 |
| 0.25 | um | Smmd 0.25 μm* | 1.30 | 0.48 | 0.28 | 0.27 | 0.64 |
| | | Poly 0.25 μm | 0.50 | 0.67 | 0.27 | 0.25 | 0.72 |
| | | Mono 0.25 μm | 0.42 | 0.64 | 0.31 | 0.29 | 0.76 |

Although the present disclosure has been described in connection with embodiments thereof, it will be appreciated by those skilled in the art that additions, deletions, modifications, and substitutions not specifically described may be made without departure from the spirit and scope of the disclosure as defined in the appended claims.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, different other components. It is to be understood that such depicted architectures are merely exemplary, and that in fact many other architectures may be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components, and/or wirelessly interactable, and/or wirelessly interacting components, and/or logically interacting, and/or logically interactable components.

In some instances, one or more components may be referred to herein as “configured to,” “configured by,” “configurable to,” “operable/operative to,” “adapted/adaptable,” “able to,” “conformable/conformed to,” etc. Those skilled in the art will recognize that such terms (e.g., “configured to”) can generally encompass active-state components and/or inactive-state components and/or standby-state components, unless context requires otherwise.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to claims containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

With respect to the appended claims, those skilled in the art will appreciate that recited operations therein may generally be performed in any order. Also, although various operational flows are presented in a sequence(s), it should be understood that the various operations may be performed in other orders than those which are illustrated or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

Those skilled in the art will appreciate that the foregoing specific exemplary processes and/or devices and/or technologies are representative of more general processes and/or devices and/or technologies taught elsewhere herein, such as in the claims filed herewith and/or elsewhere in the present application.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

The illustrative embodiments described in the detailed description, drawings, and claims are not meant to be limiting. Other embodiments may be utilized, and other changes may be made, without departing from the spirit or scope of the subject matter presented here.

Where a range of values is provided, it is understood that each intervening value, to the tenth of the unit of the lower limit unless the context clearly dictates otherwise, between the upper and lower limit of that range and any other stated or intervening value in that stated range is encompassed within the disclosure. The upper and lower limits of these smaller ranges which can independently be included in the smaller ranges is also encompassed within the disclosure, subject to any specifically excluded limit in the stated range. Where the stated range includes one or both of the limits ranges excluding either both of those included limits are also included in the disclosure.

One skilled in the art will recognize that the herein described components (e.g., operations), devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken as limiting.

Additionally, for example any sequence(s) and/or temporal order of sequence of the system and method that are described herein this disclosure are illustrative and should not be interpreted as being restrictive in nature. Accordingly, it should be understood that the process steps may be shown and described as being in a sequence or temporal order, but they are not necessarily limited to being carried out in any particular sequence or order. For example, the steps in such processes or methods generally may be carried out in various different sequences and orders, while still falling within the scope of the present disclosure.

Finally, the discussed application publications and/or patents herein are provided solely for their disclosure prior to the filing date of the described disclosure. Nothing herein should be construed as an admission that the described disclosure is not entitled to antedate such publication by virtue of prior disclosure.

1. A semiconductor wafer polishing composition, comprising:
a surface-modified monocrystalline diamond with a D(50) particle size of from 0.10 μm to 1 μm, a surface roughness of from 0.50 to 0.80, and a sphericity of less than 0.70;
a vehicle selected from the group consisting of water-based vehicles, glycol-based vehicles, oil-based vehicles, and hydrocarbon-based vehicles; and
optionally one or more additives.

2. The semiconductor wafer polishing composition of claim 1, wherein the D(50) particle size of the surface-modified monocrystalline diamond ranges from 0.25 μm to 0.50 μm.

3. The semiconductor wafer polishing composition of claim 1, wherein the D(50) particle size of the surface-modified monocrystalline diamond ranges from 0.25 μm to 0.75 μm.

4. The semiconductor wafer polishing composition of claim 3, wherein the D(50) particle size of the surface-modified monocrystalline diamond ranges from 0.50 μm to 0.75 μm.

5. The semiconductor wafer polishing composition of claim 1, wherein the D(50) particle size of the surface-modified monocrystalline diamond ranges from 0.75 μm to 1 μm.

6. The semiconductor wafer polishing composition of claim 1, wherein the one or more additives is selected from the group consisting of dispersing agents, pH modifiers, pH buffering agents, surfactants, polymers, complexing agents, rheology modifiers, chelating agents, defoamers, wetting agents, oxidizing agents, and biocides.

7. The semiconductor wafer polishing composition of claim 1, wherein a material removal rate of silicon carbide (SIC) ranges from 1.3 μm/hr to 8.2 μm/hr.

8. The semiconductor wafer polishing composition of claim 7, wherein the material removal rate of the SiC ranges from 1.3 μm/hr to 7.2 μm/hr.

9. The semiconductor wafer polishing composition of claim 8, wherein the material removal rate of the SiC ranges from 1.3 μm/hr to 3.3 μm/hr.

10.-14. (canceled)

15. The semiconductor wafer polishing composition of claim 1, wherein the surface-modified monocrystalline diamond is present in a weight of from 0.5 weight percent (wt. %) to 5 wt. % based on a total weight of the polishing composition.

16. The semiconductor wafer polishing composition of claim 15, wherein the surface-modified monocrystalline diamond is present in a weight of from 0.5 wt. % to 2.5 wt. % based on the total weight of the polishing composition.

17. The semiconductor wafer polishing composition of claim 1, wherein the vehicle is present in a volume of from 10 vol. % to 70 vol. % based on a total volume of the polishing composition.

18. The semiconductor wafer polishing composition of claim 7, wherein the SiC is monocrystalline SiC.

19. The semiconductor wafer polishing composition of claim 1, wherein the surface-modified monocrystalline diamond comprises one or more spikes, and one or more pits.

20. The semiconductor wafer polishing composition of claim 1, wherein the semiconductor wafer polishing composition excludes potassium permanganate.

21. A method for polishing a surface of a semiconductor wafer, comprising:
contacting the surface of the semiconductor wafer with a polishing pad applied with a polishing composition comprising
a surface-modified monocrystalline diamond with a D(50) particle size of from 0.10 μm to 1 μm, a surface roughness of from 0.50 to 0.80, and a sphericity of less than 0.70, a vehicle selected from the group consisting of water-based vehicles, glycol-based vehicles, oil-based vehicles, and hydrocarbon-based vehicles, and optionally one or more additives;
moving the polishing pad applied with the polishing composition relative to the semiconductor wafer; and
abrading at least a portion of the semiconductor wafer to polish the semiconductor wafer.

22. The method for polishing a surface of a semiconductor wafer of claim 21, wherein a material removal rate of silicon carbide (SIC) ranges from 1.3 μm/hr to 8.2 μm/hr.

23. The method for polishing a surface of a semiconductor wafer of claim 22, wherein the material removal rate of the SiC ranges from 1.3 μm/hr to 7.2 μm/hr.

24. The method for polishing a surface of a semiconductor wafer of claim 23, wherein the material removal rate of the SiC ranges from 1.3 μm/hr to 3.3 μm/hr.

25.-29. (canceled)

30. The method for polishing a surface of a semiconductor wafer of claim 22, wherein the SiC is monocrystalline SiC.
